(19) United States
(12) Patent Application Publication
(10) Pub. No.: US 2026/0150394 A1
(43) Pub. Date: May 28, 2026

(54) TRANSMISSION GATE STRUCTURES

(71) Applicant: Taiwan Semiconductor Manufacturing Company, Ltd., Hsinchu (TW)

(72) Inventors: Jui-Chien Huang, Hsinchu City (TW); Szuya Liao, Hsinchu (TW); Wei-Cheng Lin, Taichung City (TW); Wei-Cheng Tzeng, Taipei (TW)

(21) Appl. No.: 19/190,276

(22) Filed: Apr. 25, 2025

Related U.S. Application Data
(60) Provisional application No. 63/725,749, filed on Nov. 27, 2024.

(51) Int. Cl. H10D 84/85; H01L 23/528; H10D 30/00; H10D 30/01; H10D 62/10; H10D 62/83; H10D 62/832; H10D 84/01

(52) U.S. Cl. CPC H10D 84/851; H10D 30/502; H10D 62/121; H10D 62/83; H10D 62/832; H10D 84/0186; H10D 84/0188; H10W 20/435; H10D 30/019

(57) ABSTRACT

A semiconductor structure according to the present disclosure includes a first isolation structure, a first bottom transistor, a second bottom transistor disposed between the first isolation structure and the first bottom transistor along a direction, a first top transistor disposed over the first isolation structure, a second isolation structure over the first bottom transistor, and a second top transistor over the second bottom transistor. The second top transistor is disposed between the first top transistor and the second isolation structure along the direction.

### PRIORITY DATA

This application claims the benefit of U.S. Provisional Application No. 63/725,749, filed Nov. 27, 2024, which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that extends around a channel region to provide access to the channel region. Because its gate structure surrounds the channel regions, a GAA transistor may also be referred to as a surrounding gate transistor (SGT) or a multi-bridge-channel (MBC). The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other. The stacked device structure configuration may be arranged to perform different circuit functions.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method 100 for forming a semiconductor device according to one or more aspects of the present disclosure.

FIG. 2 illustrates a fragmentary cross-sectional view of a precursor structure, according to one or more aspects of the present disclosure.

FIG. 3 illustrates a fragmentary cross-sectional view along cross-section A-A′ in FIG. 2, according to one or more aspects of the present disclosure.

FIG. 4 illustrates a fragmentary cross-sectional view of a semiconductor structure according to a first example embodiment of the present disclosure.

FIGS. 5 and 6 illustrate fragmentary cross-sectional views along cross-section A-A′ in FIG. 4, according to one or more aspects of the present disclosure.

FIG. 7 illustrate a fragmentary cross-sectional view along cross-section B-B′ in FIG. 4, according to one or more aspects of the present disclosure.

FIGS. 8 and 9 illustrate fragmentary cross-sectional views along cross-section C-C′ in FIG. 4, according to one or more aspects of the present disclosure.

FIG. 10 illustrates a fragmentary cross-sectional view of a semiconductor structure according to a second example embodiment of the present disclosure.

FIGS. 11 and 12 illustrate fragmentary cross-sectional views along cross-section A-A′ in FIG. 10, according to one or more aspects of the present disclosure.

FIG. 13 illustrate a fragmentary cross-sectional view along cross-section B-B′ in FIG. 10, according to one or more aspects of the present disclosure.

FIGS. 14 and 15 illustrate fragmentary cross-sectional views along cross-section C-C′ in FIG. 10, according to one or more aspects of the present disclosure.

FIG. 16 illustrates a fragmentary cross-sectional view of a semiconductor structure according to a third example embodiment of the present disclosure.

FIGS. 17 and 18 illustrate fragmentary cross-sectional views along cross-section A-A′ in FIG. 16, according to one or more aspects of the present disclosure.

FIG. 19 illustrate a fragmentary cross-sectional view along cross-section B-B′ in FIG. 16, according to one or more aspects of the present disclosure.

FIGS. 20 and 21 illustrate fragmentary cross-sectional views along line C-C′ in FIG. 16, according to one or more aspects of the present disclosure.

FIG. 22 illustrates a fragmentary cross-sectional view of a semiconductor structure according to a fourth embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (CFET). The multi-gate devices in a CFET may be FinFETs or GAA transistors. A stacked multi-gate device may be implemented to realize different circuit functions. For example, a transmission gate may be implemented using stacked multi-gate construction. In logic design, a transmission gate is a transistor-based switch that allow signal passage when the control signal is high and block the signal when the control signal is low. Transmission gates may be used as building blocks for logic devices, such as a D latch or a D flip-flop.

The present disclosure provides a transmission gate structure that spans more than two contact poly pitch (CPP) in a CFET construction. The present disclosure also provides methods of forming the transmission gate structure. A method of the present disclosure includes receiving a CFET precursor structure, forming a dielectric fin through a top device structure and a bottom device structure, forming a frontside device isolation feature, forming frontside contact features and frontside jumper features, forming a frontside interconnect structure, thinning down and selectively removing a substrate of the CFET precursor structure, depositing a backside contact etch stop layer (CESL) and a backside interlayer dielectric (ILD) layer, forming a backside device isolation feature, and forming backside contact features and backside jumper features.

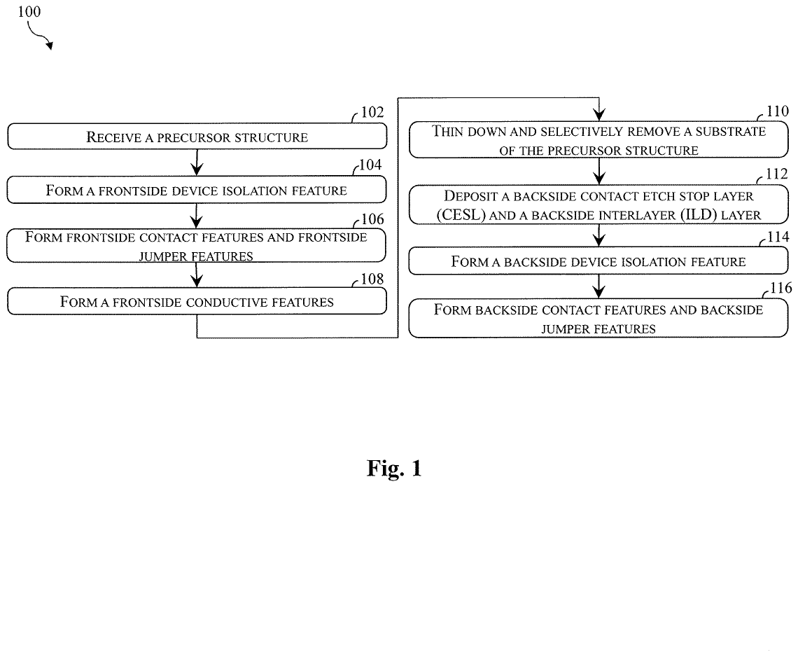

The various aspects of the present disclosure will now be described in more detail with reference to the figures. In that regard, FIG. 1 is a flowchart illustrating method 100 for forming a semiconductor device according to various aspects of the present disclosure. Method 100 is merely an example and is not intended to limit the present disclosure to what is explicitly illustrated in method 100. Additional steps may be provided before, during and after method 100, and some steps described can be replaced, eliminated, or moved around for additional embodiments of the method. Not all steps are described herein in detail for reasons of simplicity. Method 100 may be used to fabricate a semiconductor structure from a precursor structure 200. Because the precursor structure 200 is to become a semiconductor structure upon conclusion of the steps in method 100, the precursor structure 200 may be referred to as a semiconductor structure 200 as the context requires. FIGS. 1, 8, 14, and 20 illustrate four example embodiments of the semiconductor structure. Further and different variation of the semiconductor structures may be fabricated using method 100. Throughout the present application and across different embodiments, like reference numerals denote like features with similar structures and compositions, unless otherwise excepted. Source/drain region(s) may refer to a source or a drain, individually or collectively dependent upon the context.

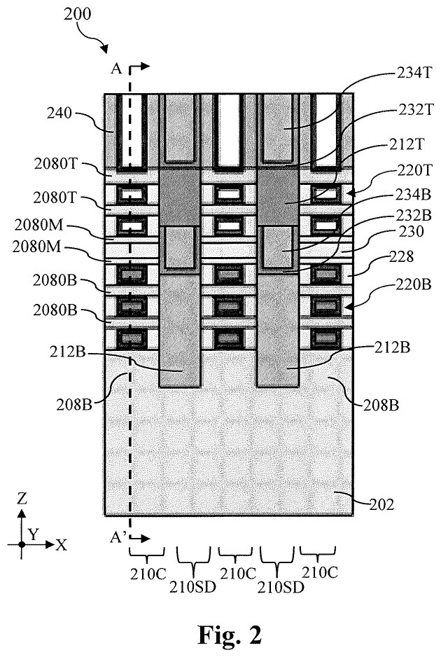

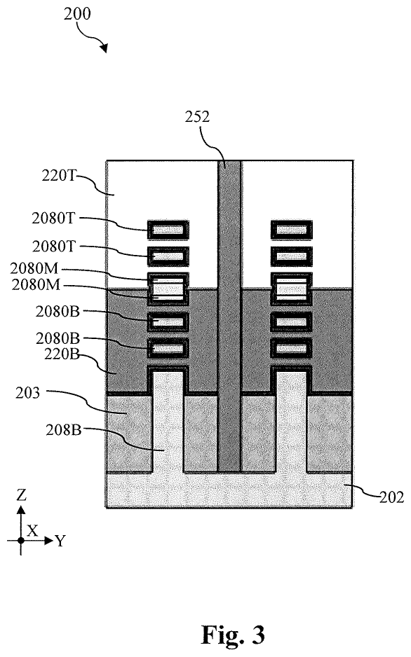

Referring to FIGS. 1, 2 and 3, method 100 includes a block 102 where a precursor structure 200 is received. In some embodiments represented in FIG. 2, the precursor structure 200 includes front-end-of-line (FEOL) CFET structures fabricated on a substrate 202. In the depicted embodiments, the FEOL CFET structures include bottom device structures formed around bottom channel members 2080B and top device structures formed around top channel members 2080T. Along a vertical direction (i.e., the Z direction), the bottom channel members 2080B is spaced apart from the top channel members 2080T by a middle dielectric layer 230 sandwiched between two middle semiconductor layers 2080M. The bottom channel members 2080B are disposed over a base fin 208B, which is patterned from the substrate 202. An isolation feature 203 (shown in FIG. 3) is disposed over the substrate 202 and surrounds the base fin 208B. The bottom channel members 2080B constitute channel regions that extend horizontally between two bottom source/drain features 212B along the X direction. Similarly, the top channel members 2080T constitute channel regions extend horizontally between two top source/drain features 212T along the X direction. In the depicted embodiments, the bottom source/drain features 212B are p-type and include silicon germanium (SiGe) doped with a p-type dopant, such as boron (B) and the top source/drain features 212T are n-type and include silicon (Si) doped with an n-type dopant, such as phosphorus (P) or arsenic (As). The bottom device structures include bottom gate structures 220B that wrap around each of the vertical stack of bottom channel members 2080B and the top device structures include top gate structures 220T that wrap around each of the vertical stack of top channel members 2080T.

Each of the top source/drain features 212T is disposed directly over one of the bottom source/drain features 212B. As shown in FIG. 2, a bottom source/drain feature 212B is spaced apart from an overlying top source/drain feature 212T by a bottom contact etch stop layer (BCESL) 232B and a bottom interlayer dielectric (BILD) layer 234B. The BILD layer 234B is spaced apart from the middle semiconductor layers 2080M and the middle dielectric layer 230 by the BCESL 232B. A top contact etch stop layer (TCESL) 232T and a top interlayer dielectric (TILD) layer 234T are disposed over each of the top source/drain features 212T. The bottom channel members 2080B are stacked one over another along the Z direction and are interleaved by inner spacer features 228. Similarly, the top channel members 2080T are stacked one over another along the Z direction and are interleaved by the inner spacer features 228. A gate spacer 240 extends along sidewalls of a portion of the top gate structure 220T above the top channel members 2080T. Due to a planarization process, top surfaces of the TCESL 232T, the TILD layer 234T, the gate spacer 240, and the top gate structures 220T are coplanar. As illustrated in FIG. 2, the bottom channel members 2080B and the top channel members 2080T fall within channel regions 210C of an active region and the bottom source/drain features 212B and the top source/drain features 212T fall with source/drain regions 210SD of the active region. A source/drain region 210SD is disposed between two channel regions 210C and a channel region 210C is disposed between two source/drain regions 210SD.

In some embodiments, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. The base fin 208B is patterned from the substrate 202 and may share the same composition with the substrate 202. In some embodiments, the bottom channel members 2080B, the middle semiconductor layers 2080M, and the top channel members 2080T may include silicon (Si). The gate spacer 240, the middle dielectric layer 230 and the inner spacer features 228 may include silicon oxide, silicon nitride, silicon oxycarbide, silicon oxycarbonitride, silicon carbonitride, metal nitride, or a suitable dielectric material. The BCESL 232B and the TCESL 232T may include silicon nitride or aluminum nitride. The BILD layer 234B and the TILD layer 234T may include an oxide-based dielectric material, such as silicon oxide, fluorine-doped silicate glass (FSG), a low-k dielectric, combinations thereof, and/or other suitable materials. The isolation feature 203 may include an oxide-based dielectric material, such as silicon oxide, fluorine-doped silicate glass (FSG), a low-k dielectric, combinations thereof, and/or other suitable materials.

In the embodiments represented in the figures, the bottom source/drain features 212B are p-type and may include silicon germanium (SiGe) doped with a p-type dopant, such as boron (B). The top source/drain features 212T are n-type and may include silicon (Si) doped with an n-type dopant, such as phosphorus (P) or arsenic (As). In these depicted embodiments, the bottom source/drain features 212B may include boron doped silicon germanium (SiGe:B) and the top source/drain features 212T may include phosphorus doped silicon (Si:P). While not explicitly shown in the figures, each of the bottom gate structures 220B and the top gate structures 220T includes an interfacial layer to interface the bottom channel members 2080B or top channel members 2080T, a gate dielectric layer over the interfacial layer, and a gate electrode over the gate dielectric layer. The gate electrode in the bottom gate structure 220B includes a p-type work function layer. The gate electrode in the top gate structure 220T includes an n-type work function layer. In some embodiments, the interfacial layer includes silicon oxide. The gate dielectric layer is formed of high-K dielectric materials. As used and described herein, high-k dielectric materials include dielectric materials having a high dielectric constant, for example, greater than that of thermal silicon oxide (˜3.9). The gate dielectric layer may include hafnium oxide. Alternatively, the gate dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. A dielectric constant of the gate dielectric layer is greater than a dielectric constant of the isolation feature 203, the inner spacer features 228, the middle dielectric layer 230, the gate spacer 240, the BCESL 232B, the BILD layer 234B, the TCESL 232T, and the TILD layer 234T. In some instances, the dielectric constant of the gate dielectric layer is more than twice of the dielectric constant of the isolation feature 203, the inner spacer features 228, the middle dielectric layer 230, the gate spacer 240, the BCESL 232B, the BILD layer 234B, the TCESL 232T, or the TILD layer 234T. Further, along the X direction, a thickness of the gate dielectric layer is smaller than a thickness of the gate spacer 240.

By way of example, the p-type work function layer in the gate electrode of the bottom gate structures 220B may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer in the gate electrode of the top gate structures 220T may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. In one embodiment, gate electrodes in the bottom gate structure 220B and the top gate structure 220T include a titanium-based material.

FIG. 3 illustrates a fragmentary cross-sectional view along cross-section A-A′ in FIG. 2. Cross-section A-A′ cuts through the gate structures 220B and 220T of the precursor structure. As illustrated in FIG. 3, the precursor structure 200 includes a dielectric fin 252 that extends through the top gate structure 220T, the bottom gate structure 220B, and the isolation feature 203. While not shown in FIG. 3, the dielectric fin 252 also extend between two neighboring top source/drain features 212T and two neighboring bottom source/drain features 212B. That is, over a source/drain region 210SD of the precursor structure, the dielectric fin 252 vertically extends through the TILD layer 234T, the TCESL 232T, the BILD layer 234B, the BCESL 232B, and the isolation feature 203. Because the dielectric fin 252 interfaces metal layers in the bottom gate structure 220B and the top gate structure 220T, the dielectric fin 252 includes an oxygen-free dielectric material, such as silicon nitride. As illustrated in FIG. 3, the dielectric fin 252 functions to divide the bottom gate structure 220B and the top gate structure 220T into two segments. For this reason, the dielectric fin 252 may be regarded as a gate cut feature or a gate isolation feature. The dielectric fin 252 extends into the isolation feature 203 and interfaces the substrate 202. While not explicitly shown in FIG. 3, the dielectric fin 252 may partially extend into the substrate 202.

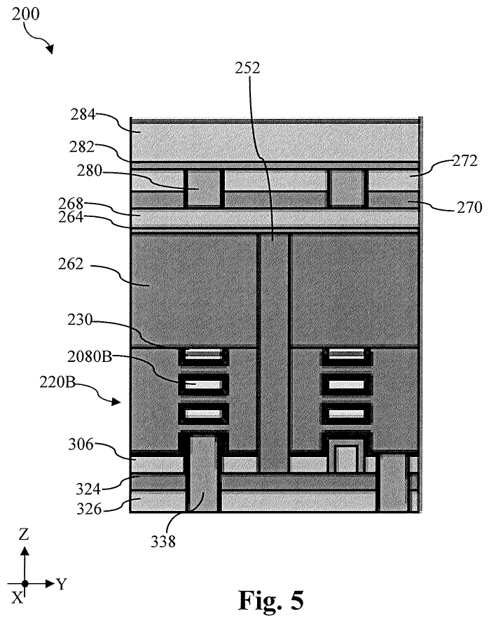

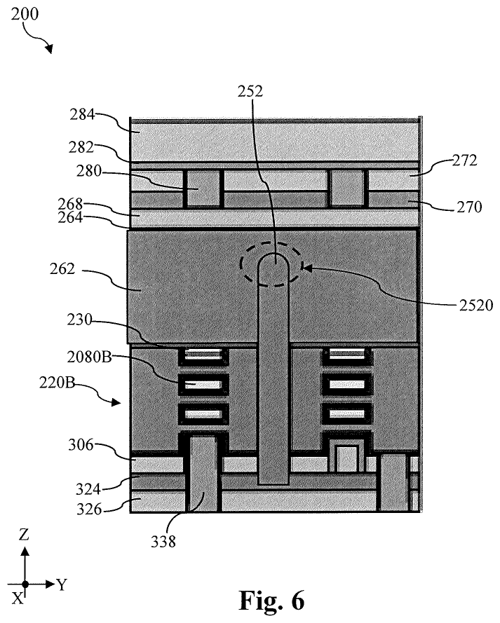

Referring to FIGS. 1, 4, 10, 16, and 22, method 100 includes a block 104 where a frontside device isolation feature is formed. To form a frontside isolation trench, a hard mask layer and a photoresist layer are deposited over the precursor structure 200. The photoresist layer is then patterned using photolithography techniques. The patterned photoresist layer is then applied as an etch mask in a dry etch process to form the frontside isolation trench through the top gate structure over the channel region 202C. The source/drain regions 202SD of the precursor structure 200 remain covered by the hard mask layer and the photoresist layer. The dry etch process at block 104 may implement an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof. In some embodiments, the frontside isolation trench removes one top gate structure 220T over a base fin 208B while the bottom gate structure 220B remain largely intact. In some alternative embodiments, top gate structures 220T on both sides of the dielectric fin 252 are removed to form side-by-side transmission gates while the dielectric fin 252 is covered by the hard mask layer. In still some alternative embodiments, the dielectric fin 252 is not covered by the hard mask layer and is etched or damaged during the formation of the frontside isolation trench. When this happens, the dielectric fin 252 may include a rounded terminal profile 2520 as shown in FIGS. 6, 12 and 18. In some implementations, the frontside isolation trench may terminate in the middle dielectric layer 230 as shown in FIGS. 5, 6, 11, 12, 17, and 18. After the formation of the frontside isolation trench, the remaining photoresist layer is removed by ashing or selective etching.

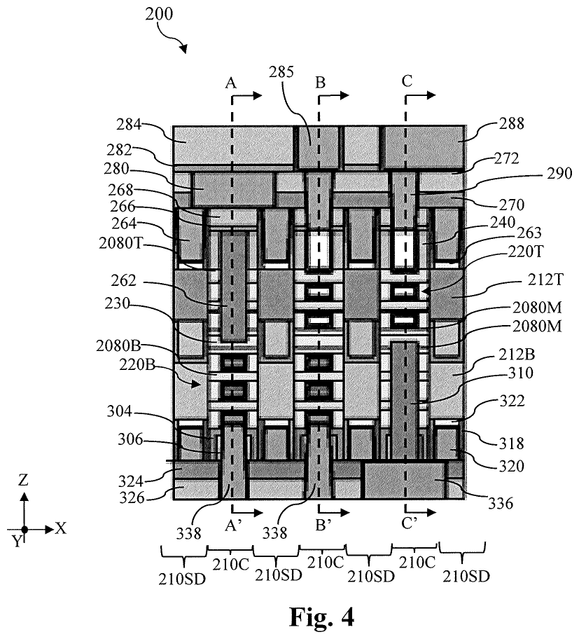

Dielectric material for the frontside device isolation feature is then deposited over the precursor structure 200, including over the frontside isolation trench. The deposition of the dielectric material at block 104 may be performed using CVD, HDP-CVD, or ALD. The dielectric material for the frontside device isolation feature is deposited not only over the frontside isolation trench but also over a top surface of the hard mask layer. A planarization process, such as a chemical mechanical polishing (CMP) process, is performed to remove the excess dielectric material over the hard mask layer to form a frontside device isolation feature 262 as shown in FIGS. 4, 10, 16, and 22. As illustrated, the frontside device isolation feature 262 functions to disable a frontside transistor by replacing a top gate structure 220T with the frontside device isolation feature 262. As shown in FIGS. 4, 10, 16, or 22, because the frontside device isolation feature 262 cuts through top channel members 2080T, sidewalls of the frontside device isolation 262 are spaced apart from sidewalls of the top source/drain features 212T by the leftover top channel members 2080T that are interleaved by inner spacer features 228.

Referring to FIGS. 1, 4, 10, 16, and 22, method 100 includes a block 106 where frontside contact features and frontside jumper features are formed. Reference is first made to FIG. 4. At block 106, a first etch stop layer (ESL) 266 and a first interlayer dielectric (ILD) layer 268 are deposited over the frontside device isolation feature 262, the gate spacer 240, the TCESL 232T, the TILD layer 234T, and the top gate structure 220T. A composition of the first ESL 266 is different from a composition of the first ILD layer 268. In some embodiments, the first ESL 266 may include silicon nitride or aluminum nitride and the first ILD layer 268 may include an oxide-based material, such as silicon oxide, fluorine-doped silicate glass (FSG), a low-k dielectric, combinations thereof, and/or other suitable materials. The first ESL 266 may be deposited using CVD and ALD. The first ILD layer 268 may be deposited using CVD, FCVD, or spin-on coating. Then, photolithography and etching processes are performed to form frontside source/drain contact openings that expose the top source/drain features 212T. The etching process to form the frontside source/drain contact openings may include a dry etch process that uses an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof. Frontside silicide features 263 are formed by bringing about silicidation between a metal layer and the top source/drain features 212T. In some embodiments, the frontside silicide features 263 may include titanium silicide. A metal fill layer is deposited using physical vapor deposition (PVD) or CVD over the frontside silicide features 263 and the frontside source/drain contact openings. A planarization process is then performed to remove excess metal fill layer to form the frontside contact features 264. In some embodiments, the frontside contact features 264 may include cobalt (Co), ruthenium (Ru), tungsten (W), nickel (Ni), or copper (Cu). A second etch stop layer (ESL) 270 and a second interlayer dielectric (ILD) layer 272 are deposited over the frontside contact features 264 and the first ILD layer 268. In some implementations, the first ESL 266 and the second ESL 270 may share a similar composition and the first ILD layer 268 and the second ILD layer 272 may share a similar composition.

Then, photolithography and etching processes are performed to form frontside gate contact openings to expose top gate structures 220T. The frontside gate contact openings extend through the second ILD layer 272, the second ESL 270, the first ILD layer 268, and the first ESL 266. The etching process for the frontside gate contact openings may include a dry etch process that uses an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof. After formation of the frontside gate contact openings, a photoresist layer is deposited over the precursor structure 200, including over the frontside gate contact opening. Then, photolithography and etching processes are performed to form a frontside jumper trench over the frontside device isolation feature 262. The frontside jumper trench extend through the second ILD layer 272 and the second ESL 270 to expose the first ILD layer 268 and the first ESL 266 over the frontside device isolation feature 262. Additionally, the frontside jumper trench also exposes two frontside contact features 264, between which lies the frontside device isolation feature 262. The etching process for the frontside jumper trench may include a dry etch process that uses an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof. After formation of the frontside jumper trench, the photoresist layer are removed to expose the frontside gate contact opening and the frontside jumper trench.

A metal fill layer is deposited over the frontside gate contact opening and the frontside jumper trench using PVD, CVD, or metalorganic CVD (MOCVD). After the deposition of the metal fill layer, a planarization process, such as a CMP process, is performed to form frontside gate contacts 290 and a frontside jumper feature 280. In some embodiments, the frontside gate contacts 290 and the frontside jumper feature 280 may include tungsten (W), ruthenium (Ru), aluminum (Al), cobalt (Co), nickel (Ni), or copper (Cu). As shown in FIG. 4, the frontside jumper feature 280 extends over the first ILD layer 268 to couple to the two frontside contact features 264. A bottom surface of the frontside jumper feature 280 is spaced apart from a top surface of the frontside device isolation feature 262 by the first ESL 266 and the first ILD layer 268. While not explicitly illustrated in the figures, a barrier layer may be deposited over the frontside gate contact opening and the frontside jumper trench before the deposition of the metal fill layer. The barrier layer may include titanium nitride (TiN), tantalum nitride (TaN), cobalt nitride (Conn), nickel nitride (NiCo), or nickel-cobalt nitride (Inco). The barrier layer reduces electromigration of the metal fill layer and slows down oxygen diffusion into the metal layer.

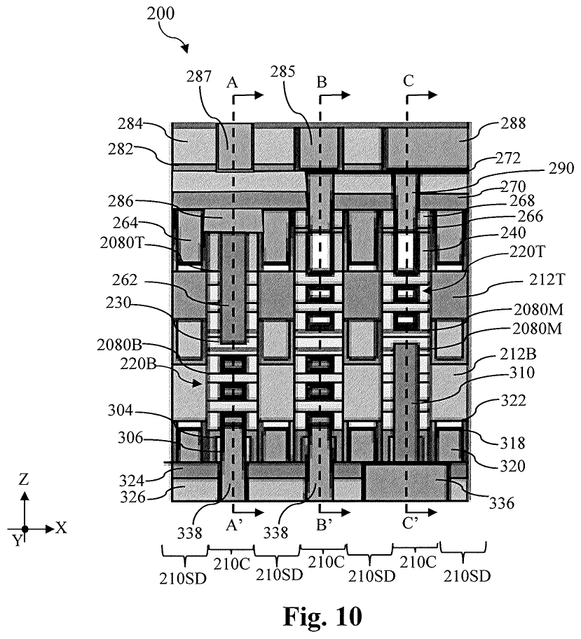

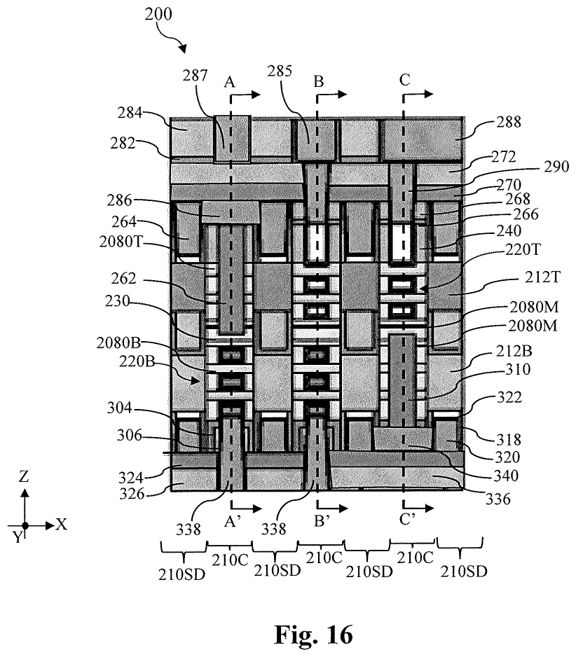

Reference is now made to FIGS. 10 and 16, which illustrates formation of a low-profile frontside jumper feature 286 according to the second and the third example embodiments. In these example embodiments, a photoresist layer is deposited and patterned to define an opening that exposes the first ILD layer 268 over the frontside device isolation feature 262 and the two frontside contact features 264 that extend along two sides of the frontside device isolation feature 262. With the patterned photoresist layer serving as an etch mask, a selective etch is performed to etch the first ILD layer 268 and the first ESL 266 to form a low-profile frontside jumper opening that exposes top surfaces of the frontside device isolation feature 262, the gate spacer 240, and the TCESL 232T. The selective etch here is configured to selectively etch the first ILD layer 268 and the first ESL 266 without substantially etching the frontside contact features 264. In some implementations, the selective etch may include use of a solution of ammonium fluoride (NH₄F) and ammonium hydroxide (NH₄OH) to etch the first ILD layer 268. The selective etch may further include a dry etch to etch through the first ESL 266. The dry etch may include use of an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof.

After formation of the low-profile frontside jumper opening, the remaining photoresist layer is removed by ashing or selective etching. Then, a metal fill layer for the low-profile frontside jumper feature 286 is deposited over the precursor structure, including the low-profile frontside jumper opening, using PVD, CVD, or MOCVD. After the deposition of the metal fill layer, a planarization process, such as a CMP process, is performed to remove excess metal fill layer over the first ILD layer 268. At this point, the low-profile frontside jumper feature 286 is formed. In some embodiments, the low-profile frontside jumper feature 286 may include tungsten (W), ruthenium (Ru), aluminum (Al), cobalt (Co), nickel (Ni), or copper (Cu). As shown in FIGS. 10 and 16, the low-profile frontside jumper feature 286 extends over the gate spacer 240 and the frontside device isolation feature 262 to couple to the two frontside contact features 264. Different from the frontside jumper feature 280 in FIG. 4, a bottom surface of the low-profile frontside jumper feature 286 interfaces the top surface of the frontside device isolation feature 262 and the gate spacer 240. This is so because the low-profile frontside jumper feature 286 is sandwiched between the two frontside contact features 264 such that the top surfaces of the low-profile frontside jumper feature 286 and the two frontside contact features 264 are coplanar. In some embodiments, the frontside gate contacts 290 may include tungsten (W), ruthenium (Ru), aluminum (Al), cobalt (Co), nickel (Ni), or copper (Cu).

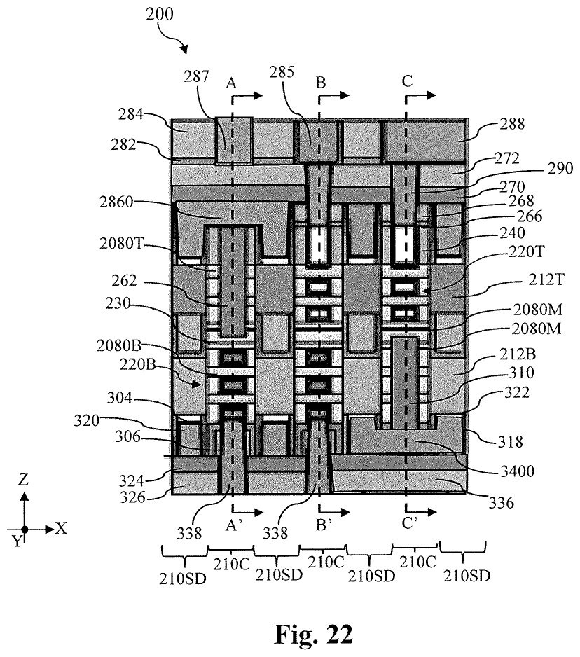

Reference is now made to FIG. 22, which illustrates formation of an integrated frontside jumper feature 2860 according to a fourth example embodiment. In the fourth example embodiment, after formation of the frontside source/drain contact openings, a photoresist layer is deposited and patterned to expose the first ILD layer 268 and the first ESL 266 over the gate spacers 240 and the frontside device isolation feature 262. A dry etch process is then performed to remove the exposed first ILD layer 268, the first ESL 266, and the TCESL 232T. After removal of the photoresist layer, a metal is deposited over the precursor structure. After a planarization process, such as a CMP process, the frontside contact features 264 and the integrated frontside jumper feature 2860 shown in FIG. 22 are form. In terms of its overall profile, the integrated frontside jumper feature 2860 is similar to a low-profile frontside jumper feature 286 and two underlying frontside contact features 264. However, the integrated frontside jumper feature 2860 is formed in a single step and is continuous. In some embodiments, the integrated frontside jumper feature 2860 may include tungsten (W), ruthenium (Ru), aluminum (Al), cobalt (Co), nickel (Ni), or copper (Cu).

When the second example embodiment, the third example embodiment, and the fourth example embodiment are adopted, the frontside gate contacts 290 are formed after the formation the low-profile frontside jumper feature 286 or the integrated frontside jumper feature 2860. As shown in FIGS. 10, 16 and 22, the frontside gate contacts 290 extend through the second ILD layer 272, the second ESL 270, the first ILD layer 268, and the first ESL 266 to interface the top gate structures 220T.

Referring to FIGS. 1, 4, 10, 16, and 22, method 100 includes a block 108 where frontside conductive features are formed. The frontside conductive features may represent conductive features in one metallization layer. Further metallization layers may be formed to complete the frontside interconnect structure. At block 108, a fourth ESL 282 and a frontside intermetal dielectric (IMD) layer 284 are deposited over the second ILD layer 272, the frontside gate contacts 290, and the frontside jumper feature 280, as shown in FIGS. 4, 10, 16, or 22. A composition of the fourth ESL 282 is different from a composition of the frontside IMD layer 284. In some embodiments, the fourth ESL 282 may include silicon nitride, aluminum nitride, or aluminum oxide and the frontside IMD layer 284 may include an oxide-based dielectric material, such as silicon oxide, fluorine-doped silicate glass (FSG), a low-k dielectric, combinations thereof, and/or other suitable materials. After formation of the fourth ESL 282 and the frontside IMD layer 284, frontside conductive features are formed. In the first example embodiment illustrated in FIG. 4, the frontside conductive features include a first conductive feature 285 and a second conductive feature 288. In the second, third and fourth example embodiments illustrated in FIGS. 10, 16, and 22, an additional third conductive feature 287, which may be a metal line, may be formed over the low-profile frontside jumper feature 286 or the integrated frontside jumper feature 2860 as the low-profile frontside jumper feature 286 or the integrated frontside jumper feature 2860 does not extend into the second ILD layer 272 and the second ESL 270, which provides electrical isolation along the vertical direction. The first conductive feature 285 is coupled to the frontside gate contact 290 in the middle of the precursor structure 200 in FIG. 4, 10, 16, or 20 and the second conductive feature 288 is coupled to the frontside gate contact 290 apart from the frontside jumper feature 280. In some embodiments, the first conductive feature 285, the second conductive feature 288, and the third conductive feature 287 (when present) may include copper (Cu), cobalt (Co), nickel (Ni), ruthenium (Ru), tungsten (W), or titanium nitride (TiN).

Referring to FIG. 1, method 100 includes a block 110 where the substrate 202 (shown in FIGS. 2 and 3) of the precursor structure 200 is thinned down and selectively removed. Operations at block 110 includes thinning the substrate 202 (shown in FIGS. 2 and 3) and selective removal of the substrate 202 (shown in FIGS. 2 and 3). After the formation of the frontside conductive features at block 108, the precursor structure 200 is flipped upside down and bonded to a carrier substrate (not shown). In some embodiments, the carrier substrate may include silicon, quartz, or glass. The precursor structure 200 may be bonded to the carrier substrate by an adhesion film that is curable using ultraviolet radiation or heat. The substrate 202 is then thinned down using a combination of grinding and polishing processes until the isolation feature 203 and the dielectric fin 252 are exposed in a backside surface of the precursor structure 200. After the substrate 202 is thinned, the base fins 208B (shown in FIGS. 2 and 3) may be selectively removed using a dry etch process or a wet etch process. An example dry etch process includes use of hydrogen bromide (HBr), nitrogen trifluoride (NF₃), oxygen (O₂), bromotrifluoromethane (CF₃Br), chlorine (Cl₂), or a combination thereof. An example wet etch process includes use of a solution of ammonium hydroxide (NH₄OH), tetramethylammonium hydroxide (TMAH), or a combination thereof. The selective removal of the base fins 208B form backside trenches that terminate in the bottom gate structure 220B.

Referring to FIGS. 1, 4, 10, 16, and 22, method 100 includes a block 112 where a first backside etch stop layer (ESL) 304 and a first backside interlayer (ILD) layer 306 are deposited. As illustrated in FIG. 4, 10, 16, or 22, a first backside ESL 304 and a first backside ILD layer 306 are deposited over the backside surface of the precursor structure 200, including over the backside trenches leading to the bottom surfaces of the bottom gate structures 220B. In some embodiments, the first backside ESL 304 may be similar to the first ESL 266 in terms of composition and formation methods. The first backside ILD layer 306 may be similar to the first ILD layer 268 in terms of composition and formation methods. A planarization process, such as a CMP process, is performed to remove excess first backside ESL 304 and excess first backside ILD layer 306. In some embodiments, the planarization is performed until the bottom source/drain features 212B are exposed in the backside surface of the precursor structure 200. In some embodiments, the planarization also exposes the dielectric fin 252. After the planarization, a portion of the first backside ESL 304 and a portion of the first backside ILD layer 306 remain disposed over the bottom gate structure 220B along the-Z direction (the precursor structure 200 being upside down) and between two adjacent bottom source/drain features 212B along the X direction.

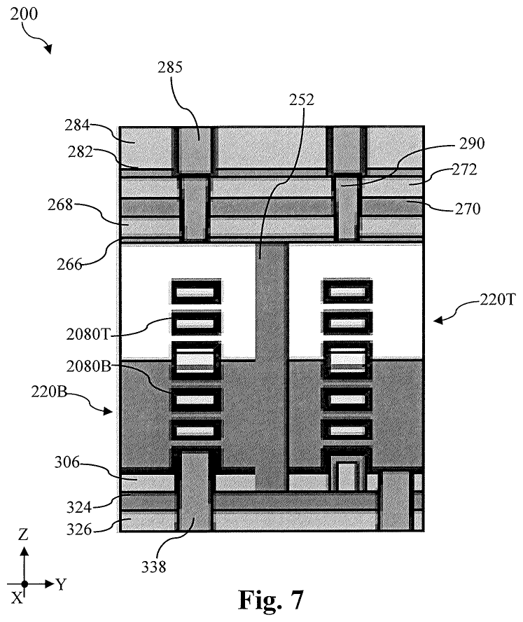

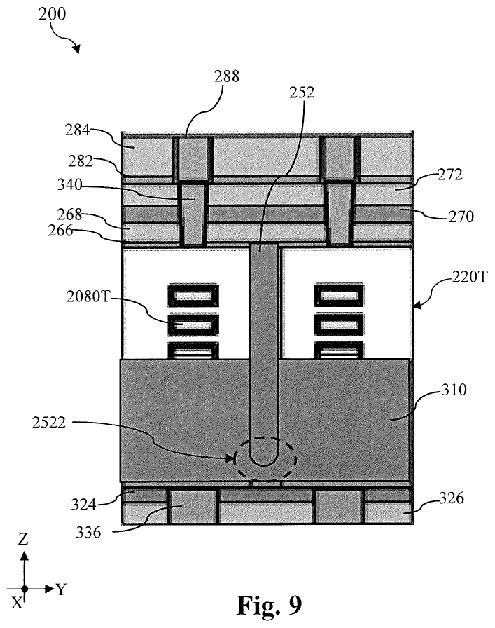

Referring to FIGS. 1, 4, 10, 16, and 22, method 100 include a block 114 where a backside device isolation feature 310 is formed. To form a backside isolation trench, a hard mask layer and a photoresist layer are deposited over a back side of the precursor structure 200. The photoresist layer is then patterned using photolithography techniques. The patterned photoresist layer is then applied as an etch mask in a dry etch process to form the backside isolation trench. The source/drain regions of the precursor structure 200 remain covered by the hard mask layer and the photoresist layer. The dry etch process at block 114 may implement an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof. Formation of the backside isolation trench removes at least one bottom gate structure 220B over a top gate structure 220T while the top gate structure 220T remains largely intact. In some embodiments, both bottom gate structures 220B on both sides of the dielectric fin 252 (shown in FIGS. 7-9 and 13-15) are removed. In some implementations, the backside isolation trench may terminate in the middle dielectric layer 230, as shown in FIGS. 4, 10, 16, and 22. In the depicted embodiments, the etching of the backside isolation trench may not substantially etch the dielectric fin 252. After the formation of the backside isolation trench, the remaining photoresist layer and the hard mask layer are removed by ashing or selective etching. In some alternative embodiments, the dielectric fin 252 is etched or damaged during formation of the backside isolation trench such that it has a rounded terminal profile 2522, as illustrated in FIGS. 9, 15 and 21.

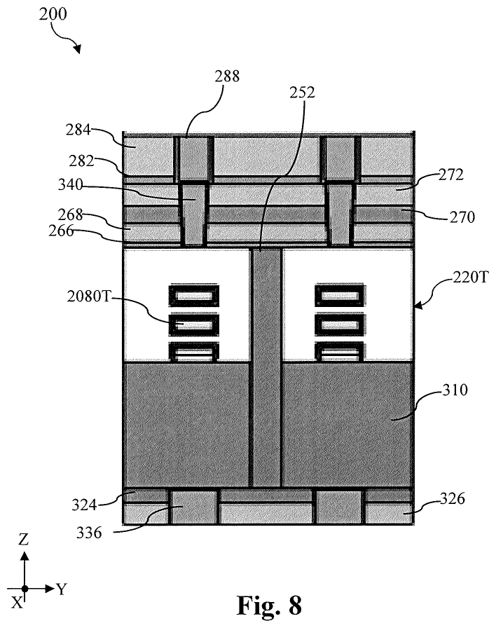

After the formation of the backside isolation trench, dielectric material for the backside device isolation feature 310 is deposited over the precursor structure 200, including over the backside isolation trench. The deposition of the dielectric material at block 114 may be performed using CVD, HDP-CVD, or ALD. The dielectric material for the backside device isolation feature 310 is deposited not only over the backside isolation trench but also over a bottom surface of the isolation feature 203 (shown in FIG. 3) to cover the first backside ESL 304 and the first backside ILD layer 306. A planarization process, such as a CMP process, is performed to remove the excess dielectric material over the isolation feature 203 (shown in FIG. 3), the first backside ESL 304 and the first backside ILD layer 306. The dielectric material in the backside isolation trench forms the backside device isolation feature 310 shown in FIGS. 4, 8, 9, 10, 14, 15, 16, 20, 21, and 22. Referring to FIGS. 1, 10, 16, and 22, along a channel length direction (i.e., the X direction), the backside device isolation feature 310 is disposed between two bottom source/drain features 212B. Sidewalls of the backside device isolation feature 310 are spaced apart from the bottom source/drain features 212B by remaining portions of the bottom channel members 2080B that are interleaved by the inner spacer features 228. Referring to FIGS. 8, 9, 14, 15, 20, and 21, the backside device isolation feature 310 interfaces the top gate structures 220T, the middle dielectric layer 230, and sidewalls of the dielectric fin 252.

Referring to FIGS. 1, 4 and 10, method 100 includes a block 116 where backside contact features 320 and a backside jumper feature 336 are formed. At block 116, a hard mask layer and a photoresist layer are deposited over the back side of the precursor structure 200. Here, the mask layer may be a multilayer that includes an oxygen-free dielectric layer to directly interface the bottom source/drain features 212B and a low-k dielectric layer over the oxygen-free dielectric layer. In some embodiments, the oxygen-free dielectric layer includes silicon nitride and the low-k dielectric layer include silicon oxide. The photoresist layer is then patterned using photolithography techniques to form a patterned photoresist layer over the hard mask layer. The patterned photoresist layer is then applied as an etch mask to etch the hard mask layer to form backside contact openings. Bottom surfaces of the bottom source/drain features 212B are exposed in the backside contact openings. The etching process to form the backside contact openings may include a dry etch process that uses an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof. Backside silicide features 322 are then formed by bringing about silicidation between a metal layer and the bottom source/drain features 212B. In some embodiments, the backside silicide features 322 may include titanium silicide. A metal fill layer is deposited using physical vapor deposition (PVD) or CVD over the backside silicide features 322 and the backside contact openings. A planarization process is then performed to remove excess metal fill layer to form the backside contact features 320. In some embodiments, the backside contact features 320 may include cobalt (Co), ruthenium (Ru), tungsten (W), nickel (Ni), or copper (Cu). In some embodiments presented in FIGS. 4, 10, 16, and 22, sidewalls of the backside contact features 320 may be lined by a barrier layer 318. The barrier layer 318 may be conformally deposited before the deposition of the metal fill. In some embodiments, the barrier layer 318 may include silicon nitride, aluminum nitride, titanium nitride, or tantalum nitride.

A first backside ESL 324 and a second backside ILD layer 326 are deposited over backside contact features 320 and backside device isolation feature 310. In some embodiments, the first backside ESL 324 may include silicon nitride or aluminum nitride and the second backside ILD layer 326 may include an oxide-based material, such as silicon oxide, fluorine-doped silicate glass (FSG), a low-k dielectric, combinations thereof, and/or other suitable materials. The first backside ESL 324 may be deposited using CVD and ALD. The second backside ILD layer 326 may be deposited using CVD, FCVD, or spin-on coating. A photoresist layer is deposited over the second backside ILD layer 326. Then, photolithography and etching processes are performed to form backside gate contact openings to expose bottom gate structures 220B. The backside gate contact openings extend through the second backside ILD layer 326, the first backside ESL 324, the first backside ILD layer 306, and the first backside ESL 304. The etching process for the backside gate contact openings may include a dry etch process that uses an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof. The bottom gate structures 220B are exposed in the backside gate contact openings.

After formation of the backside gate contact openings, a photoresist layer is deposited over the back side of the precursor structure 200, including over the backside gate contact openings. Then, photolithography and etching processes are performed to form a backside jumper trench over the backside device isolation feature 310. The backside jumper trench extend through the second backside ILD layer 326 and the first backside ESL 324 to expose backside device isolation feature 310, the first backside ILD layer 306, and the first backside ESL 304. Additionally, the backside jumper trench also exposes two backside contact features 320, between which lies the backside device isolation feature 310. The etching process for the backside jumper trench may include a dry etch process that uses an oxygen-containing gas (e.g., O₂), a fluorine-containing gas (e.g., SF₆, CH₃F, C₄F₆, CH₂F₂, or NF₃), a chlorine-containing gas (e.g., Cl₂, SiCl₄, and/or BCl₃), a bromine-containing gas (e.g., HBr), an iodine-containing gas, other suitable gases and/or plasmas, and/or combinations thereof. After formation of the backside jumper trench, the photoresist layers are removed to expose the backside gate contact openings and the backside jumper trench.

A metal fill layer is deposited over the backside gate contact openings and the backside jumper trench using PVD, CVD, or metalorganic CVD (MOCVD). After the deposition of the metal fill layer, a planarization process, such as a CMP process, is performed to form backside gate contacts 338 and a backside jumper feature 336. In some embodiments, the backside gate contacts 338 and the backside jumper feature 336 may include tungsten (W), ruthenium (Ru), aluminum (Al), cobalt (Co), nickel (Ni), or copper (Cu). As shown in FIG. 4 or 10, the backside jumper feature 336 extends over the backside device isolation feature 310 to couple to the two backside contact features 320. A top surface of the backside jumper feature 336 interfaces with a bottom surface of the backside device isolation feature 310. While not explicitly illustrated in the figures, a barrier layer may be deposited over the backside gate contact openings and the backside jumper trench before the deposition of the metal fill layer. The barrier layer may include titanium nitride (TiN), tantalum nitride (TaN), cobalt nitride (CoN), nickel nitride (NiCo), or nickel-cobalt nitride (NiCoN). The barrier layer reduces electromigration of the metal fill layer and slows down oxygen diffusion into the metal layer.

In the first and second example embodiments are illustrated in FIGS. 4 and 10 respectively, the backside jumper feature 336 is disposed in the second backside ILD layer 326 and the first backside ESL 324 below the backside contact features 320. FIG. 16 illustrate a low-profile backside jumper feature 340. Rather than interfacing the bottom surfaces of the backside contact features 320, the low-profile backside jumper feature 340 is disposed between two backside contact features 320 along the X direction. That is, the second backside ILD layer 326 and the first backside ESL 324 are disposed below the bottom surfaces of the low-profile backside jumper feature 340 and the backside contact features 320. To form the low-profile backside jumper feature 340, photolithography and etch processes are utilized to selectively etch the first backside ESL 304, first backside ILD 306, and the backside device isolation feature 310 between two backside contact features 320. The low-profile backside jumper feature 340 is formed after a metal fill is deposited and a planarization is performed to remove excess materials. FIG. 22 illustrates an integrated backside jumper feature 3400 where a metal fill is deposited to form the backside contact trench and the low-profile backside jumper trench together.

Semiconductor structure 200 according to the present disclosure includes a frontside jumper feature and a backside jumper feature. The frontside jumper feature may be implemented using the frontside jumper feature 280, the low-profile frontside jumper feature 286, or the integrated frontside jumper feature 2860. The backside jumper feature may be implemented using the backside jumper feature 336, the low-profile backside jumper feature 340, or the integrated backside jumper feature 3400.

FIG. 4 illustrates a semiconductor structure 200 according to a first example embodiment of the present disclosure. The semiconductor structure 200 in FIG. 4 includes a frontside jumper feature 280 and a backside jumper feature 336. FIGS. 5 and 6 illustrate two alternative cross-sectional view along cross-section A-A′ in FIG. 4. In FIG. 5, the frontside surface of the dielectric fin 252 is coplanar with the top surface of the frontside device isolation feature 262 because the dielectric fin 252 is covered and protected when the frontside device isolation feature 262 is formed. In FIG. 6, the frontside surface of the dielectric fin 252 has a rounded terminal profile 2520 because the dielectric fin 252 is etched when the frontside device isolation feature 262 is formed. FIG. 7 illustrate a cross-sectional view along cross-section B-B′ in FIG. 4. FIGS. 8 and 9 illustrate two alternative cross-sectional view along cross-section C-C′ in FIG. 4. In FIG. 8, the backside surface of the dielectric fin 252 is coplanar with the bottom surface of the backside device isolation feature 310 because the dielectric fin 252 is covered and protected when the backside device isolation feature 310 is formed. In FIG. 9, the backside surface of the dielectric fin 252 has a rounded terminal profile 2522 because the dielectric fin 252 is etched when the backside device isolation feature 310 is formed.

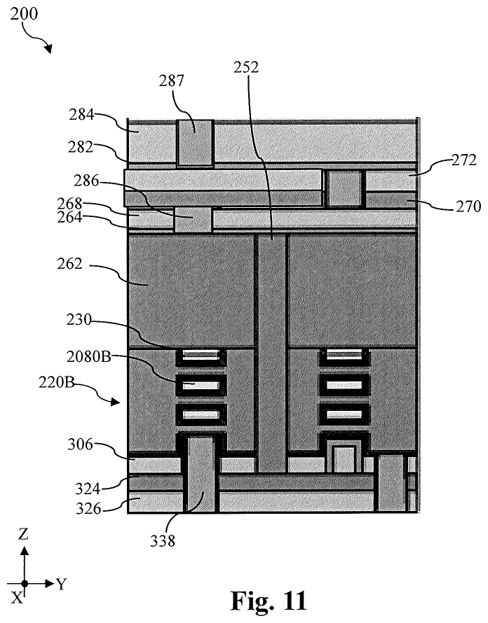

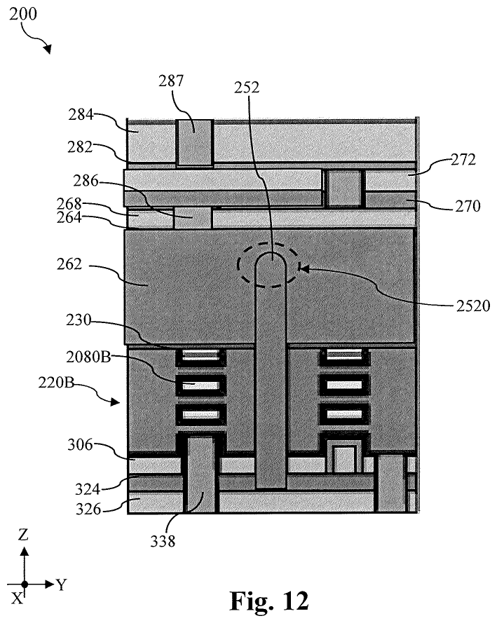

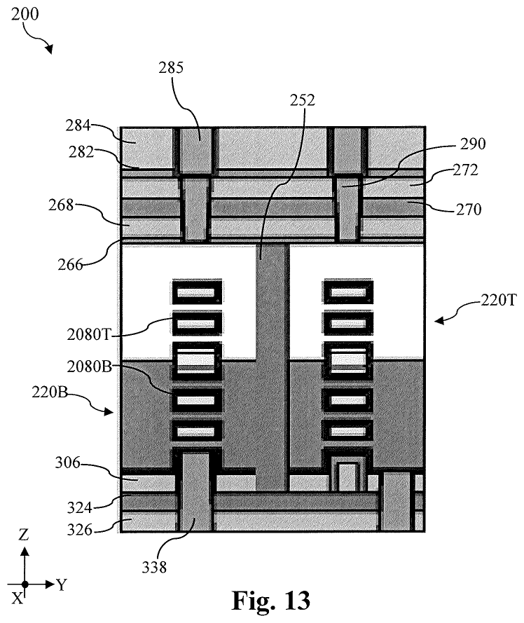

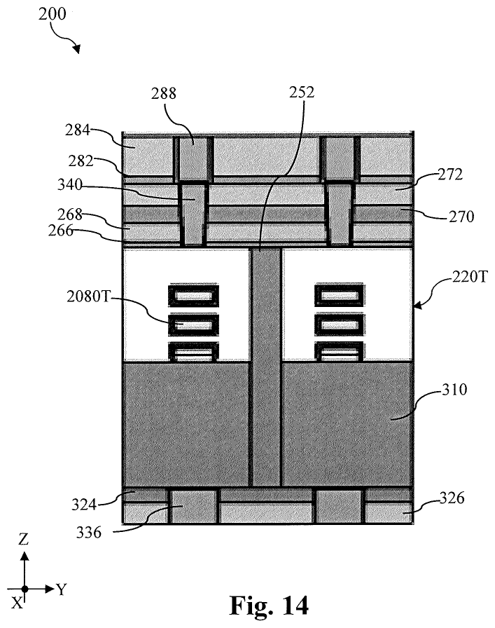

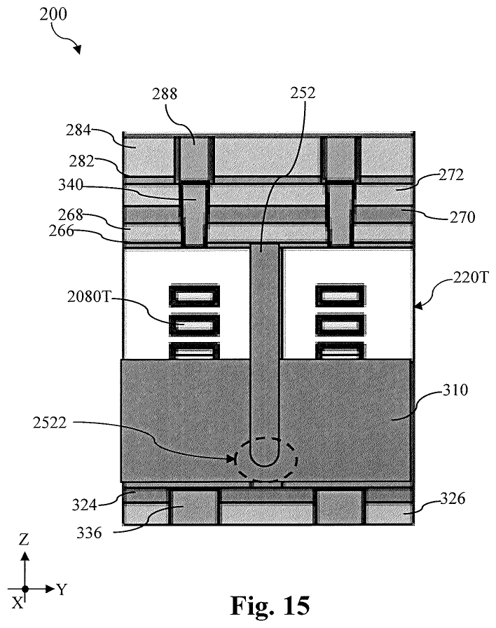

FIG. 10 illustrates a semiconductor structure 200 according to a second example embodiment of the present disclosure. The semiconductor structure 200 in FIG. 10 includes a low-profile frontside jumper feature 286 and a backside jumper feature 336. FIGS. 11 and 12 illustrate two alternative cross-sectional view along cross-section A-A′ in FIG. 10. In FIG. 11, the frontside surface of the dielectric fin 252 is coplanar with the top surface of the frontside device isolation feature 262 because the dielectric fin 252 is covered and protected when the frontside device isolation feature 262 is formed. In FIG. 12, the frontside surface of the dielectric fin 252 has a rounded terminal profile 2520 because the dielectric fin 252 is etched when the frontside device isolation feature 262 is formed. FIG. 13 illustrate a cross-sectional view along cross-section B-B′ in FIG. 10. FIGS. 14 and 15 illustrate two alternative cross-sectional view along cross-section C-C′ in FIG. 10. In FIG. 14, the backside surface of the dielectric fin 252 is coplanar with the bottom surface of the backside device isolation feature 310 because the dielectric fin 252 is covered and protected when the backside device isolation feature 310 is formed. In FIG. 15, the backside surface of the dielectric fin 252 has a rounded terminal profile 2522 because the dielectric fin 252 is etched when the backside device isolation feature 310 is formed.

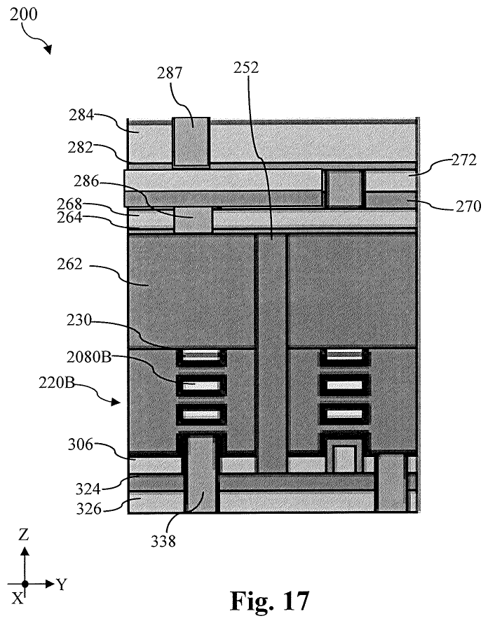

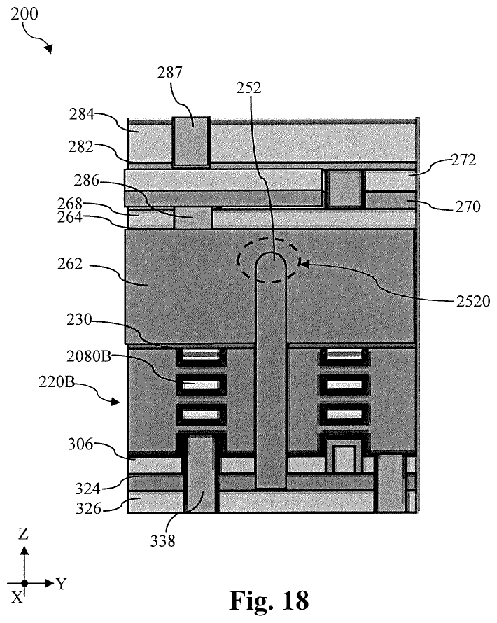

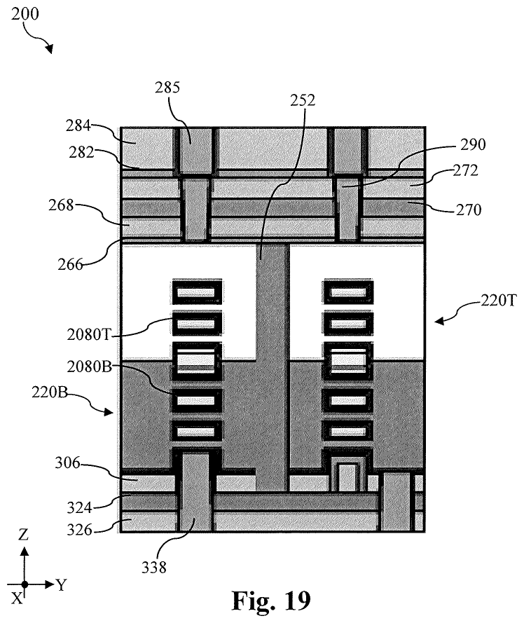

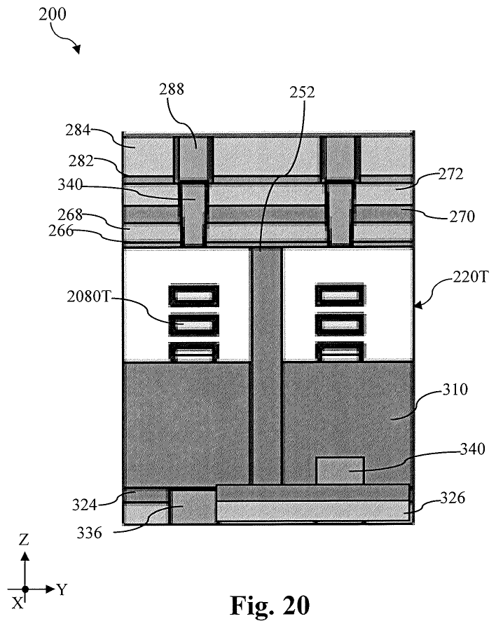

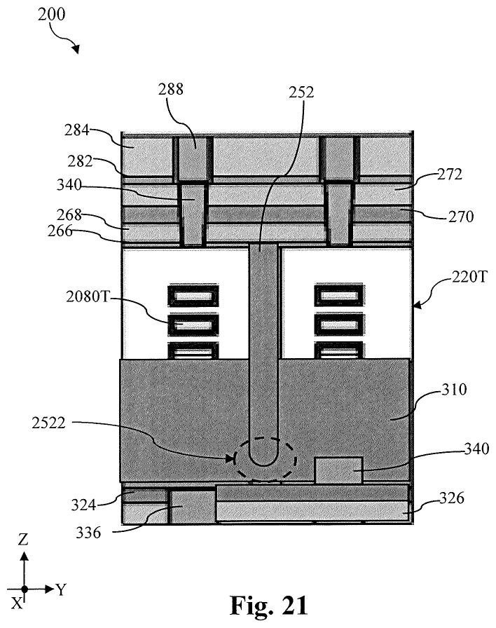

FIG. 16 illustrates a semiconductor structure 200 according to a third example embodiment of the present disclosure. The semiconductor structure 200 in FIG. 16 includes a low-profile frontside jumper feature 286 and a low-profile backside jumper feature 340. FIGS. 17 and 18 illustrate two alternative cross-sectional view along cross-section A-A′ in FIG. 16. In FIG. 17, the frontside surface of the dielectric fin 252 is coplanar with the top surface of the frontside device isolation feature 262 because the dielectric fin 252 is covered and protected when the frontside device isolation feature 262 is formed. In FIG. 18, the frontside surface of the dielectric fin 252 has a rounded terminal profile 2520 because the dielectric fin 252 is etched when the frontside device isolation feature 262 is formed. FIG. 19 illustrate a cross-sectional view along cross-section B-B′ in FIG. 16. FIGS. 20 and 21 illustrate two alternative cross-sectional view along cross-section C-C′ in FIG. 16. In FIG. 20, the backside surface of the dielectric fin 252 is coplanar with the bottom surface of the backside device isolation feature 310 because the dielectric fin 252 is covered and protected when the backside device isolation feature 310 is formed. In FIG. 21, the backside surface of the dielectric fin 252 has a rounded terminal profile 2522 because the dielectric fin 252 is etched when the backside device isolation feature 310 is formed. As shown in FIGS. 20 and 21, the low-profile backside jumper feature 340 is disposed in the backside device isolation feature 310.

FIG. 22 illustrates a semiconductor structure 200 according to a fourth example embodiment of the present disclosure. The semiconductor structure 200 in FIG. 20 includes an integrated frontside jumper feature 2860 and an integrated backside jumper feature 3400.

Reference is finally made to FIGS. 4, 10, 16, and 22. In terms of electrical connections that are needed for the transmission gate device to operate, the top gate structure 220T over the backside device isolation feature 310 and the bottom gate structure 220B below the frontside device isolation feature 262 are electrically connected by way of the frontside gate contact 290, the backside gate contact 338, the frontside interconnect structure and the backside interconnect structure. The top gate structure 220T and the bottom gate structure 220B in the middle (along cross-section C-C′) interface with one another and are electrically coupled together. Because the middle top gate structure 220T and the bottom gate structure 220B are electrically coupled, only one of them is required to be electrically coupled to a gate contact. That is, only one backside gate contact 338 to the middle bottom gate structure 220B or one frontside gate contact 290 to the middle top gate structure 220T is required. The backside and frontside jumper structures, such as the frontside jumper feature 280, the backside jumper feature 336, the low-profile frontside jumper structure 286, the low-profile backside jumper feature 340, the integrated frontside jumper feature 2860, and the integrated backside jumper feature 3400 are needed for the input and output of the transmission gate device formed according to the present disclosure.

In one exemplary aspect, the present disclosure is directed to a semiconductor structure. The semiconductor structure includes a first isolation structure, a first bottom transistor, a second bottom transistor disposed between the first isolation structure and the first bottom transistor along a direction, a first top transistor disposed over the first isolation structure, a second isolation structure over the first bottom transistor, and a second top transistor over the second bottom transistor. The second top transistor is disposed between the first top transistor and the second isolation structure along the direction. The first bottom transistor includes a gate structure. The gate structure of the first bottom transistor includes a gate dielectric layer and a gate electrode. The gate electrode includes a titanium-based material.

In some embodiments, the first isolation structure is disposed between a first bottom source/drain feature and a second bottom source/drain feature along the direction. A first jumper structure is disposed below the first isolation structure, the first bottom source/drain feature and the second bottom source/drain feature. In some embodiments, the semiconductor structure further includes a first backside contact disposed between the first jumper structure and the first bottom source/drain feature, and a second backside contact disposed between the first jumper structure and the second bottom source/drain feature. In some instances, the first jumper structure interfaces the first isolation structure. In some implementations, the second bottom transistor includes a first gate structure, the second top transistor includes a second gate structure, and the first gate structure interfaces the second gate structure. In some embodiments, the semiconductor structure further includes a backside gate contact interfacing the first gate structure. Bottom surfaces of the first jumper structure and the backside gate contact are coplanar. In some embodiments, the semiconductor structure further includes a second jumper structure disposed over the second isolation structure. The second jumper structure interfaces a top surface of the second isolation structure. In some embodiments, the first bottom source/drain feature and the second bottom source/drain feature include silicon germanium and a p-type dopant. In some embodiments, along the direction, the first isolation structure is spaced apart from the first bottom source/drain feature by a plurality of semiconductor features and a plurality of inner spacer features. In some instances, the plurality of semiconductor features include silicon.

In another exemplary aspect, the present disclosure is directed to a semiconductor structure. The semiconductor structure includes a backside dielectric layer, a first jumper feature disposed in the backside dielectric layer, a first backside contact and a second backside contact interfacing a top surface of the first jumper feature, a first bottom source/drain feature disposed over and electrically coupled to the first backside contact, a second bottom source/drain feature disposed over and electrically coupled to the second backside contact, a first isolation feature disposed between the first backside contact and the second backside contact as well as between the first bottom source/drain feature and the second bottom source/drain feature, a first top source/drain feature over the first bottom source/drain feature, a second top source/drain feature over the second bottom source/drain feature, a first plurality of channel members over the first isolation feature and extending between the first top source/drain feature and the second top source/drain feature, and a first gate structure wrapping around each of the first plurality of channel members. The first isolation feature is disposed over and interfacing the first jumper feature. The first gate structure includes a gate dielectric layer and a gate electrode. A dielectric constant of the gate dielectric layer is greater than a dielectric constant of the backside dielectric layer.

In some embodiments, the first bottom source/drain feature and the second bottom source/drain feature include silicon germanium and a p-type dopant. The first top source/drain feature and the second top source/drain feature include silicon and an n-type dopant. In some implementations, the first isolation feature is spaced apart from a sidewall of the first bottom source/drain feature by a plurality semiconductor features and a plurality of dielectric features. In some implementations, a top surface of the first isolation feature is spaced apart from a bottom surface of the first gate structure by a middle dielectric layer and a semiconductor layer. In some embodiments, the semiconductor structure further includes a second plurality of channel members extending between the second bottom source/drain feature and a third bottom source/drain feature, a second gate structure wrapping around each of the second plurality of channel members, a third plurality of channel members extending between the second top source/drain feature and a third top source/drain feature, a third gate structure wrapping around each of the third plurality of channel members, a fourth plurality of channel members extending between the third bottom source/drain feature and a fourth bottom source/drain feature, a fourth gate structure wrapping around each of the fourth plurality of channel members, and a second isolation feature is disposed over the fourth gate structure. In some embodiments, the semiconductor structure further includes a fourth top source/drain feature such that the second isolation feature is disposed between the third top source/drain feature and the fourth top source/drain feature, a first frontside contact feature disposed over the third top source/drain feature, a second frontside contact feature disposed over the fourth top source/drain feature, and a second jumper feature interfacing the first frontside contact feature and the second frontside contact feature.

In yet another exemplary aspect, the present disclosure is directed to a device structure. The device structure includes a first bottom transistor including a first plurality of nanostructures extending between a first bottom source/drain feature and a second bottom source/drain feature along a direction, a first top transistor disposed over the first bottom transistor and including a second plurality of nanostructures extending between a first top source/drain feature and a second top source/drain feature along the direction, a second top transistor sharing the first top source/drain feature with the first top transistor, a second bottom transistor sharing the second bottom source/drain feature with the first bottom transistor, a bottom isolation feature disposed below the second top transistor, a top isolation feature disposed over the second bottom transistor, a first jumper feature disposed below the bottom isolation feature, a second jumper feature disposed over the top isolation feature, a backside etch stop layer disposed below the first jumper feature, and a backside dielectric layer below the backside etch stop layer. A composition of the backside etch stop layer is different from a composition of the backside dielectric layer.

In some embodiments, a bottom surface of the bottom isolation feature interfaces a top surface of the first jumper feature. In some implementations, a top surface of the top isolation feature is spaced apart from a bottom surface of the second jumper feature by an etch stop layer and an interlayer dielectric layer. In some embodiments, the first bottom source/drain feature is spaced apart from a sidewall of the bottom isolation feature by a plurality of semiconductor features and a plurality of dielectric features.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first isolation structure;
a first bottom transistor;
a second bottom transistor disposed between the first isolation structure and the first bottom transistor along a direction;
a first top transistor disposed over the first isolation structure;
a second isolation structure over the first bottom transistor; and
a second top transistor over the second bottom transistor,
wherein the second top transistor is disposed between the first top transistor and the second isolation structure along the direction,
wherein the first bottom transistor comprises a gate structure,
wherein the gate structure of the first bottom transistor comprises a gate dielectric layer and a gate electrode,
wherein the gate electrode comprises a titanium-based material.

2. The semiconductor structure of claim 1,
wherein the first isolation structure is disposed between a first bottom source/drain feature and a second bottom source/drain feature along the direction,
wherein a first jumper structure is disposed below the first isolation structure, the first bottom source/drain feature and the second bottom source/drain feature.

3. The semiconductor structure of claim 2, further comprising:
a first backside contact disposed between the first jumper structure and the first bottom source/drain feature; and
a second backside contact disposed between the first jumper structure and the second bottom source/drain feature.

4. The semiconductor structure of claim 2, wherein the first jumper structure interfaces the first isolation structure.

5. The semiconductor structure of claim 2,
wherein the second bottom transistor comprises a first gate structure,
wherein the second top transistor comprises a second gate structure,
wherein the first gate structure interfaces the second gate structure.

6. The semiconductor structure of claim 5, further comprising:
a backside gate contact interfacing the first gate structure,
wherein bottom surfaces of the first jumper structure and the backside gate contact are coplanar.

7. The semiconductor structure of claim 2, further comprising:
a second jumper structure disposed over the second isolation structure,
wherein the second jumper structure interfaces a top surface of the second isolation structure.

8. The semiconductor structure of claim 2, wherein the first bottom source/drain feature and the second bottom source/drain feature comprise silicon germanium and a p-type dopant.

9. The semiconductor structure of claim 2, wherein, along the direction, the first isolation structure is spaced apart from the first bottom source/drain feature by a plurality of semiconductor features and a plurality of inner spacer features.

10. The semiconductor structure of claim 9, wherein the plurality of semiconductor features comprise silicon.

11. A semiconductor structure, comprising:
a backside dielectric layer;
a first jumper feature disposed in the backside dielectric layer;
a first backside contact and a second backside contact interfacing a top surface of the first jumper feature;
a first bottom source/drain feature disposed over and electrically coupled to the first backside contact;
a second bottom source/drain feature disposed over and electrically coupled to the second backside contact;
a first isolation feature disposed between the first backside contact and the second backside contact as well as between the first bottom source/drain feature and the second bottom source/drain feature;
a first top source/drain feature over the first bottom source/drain feature;
a second top source/drain feature over the second bottom source/drain feature;
a first plurality of channel members over the first isolation feature and extending between the first top source/drain feature and the second top source/drain feature; and
a first gate structure wrapping around each of the first plurality of channel members,
wherein the first isolation feature is disposed over and interfacing the first jumper feature,
wherein the first gate structure comprises a gate dielectric layer and a gate electrode,
wherein a dielectric constant of the gate dielectric layer is greater than a dielectric constant of the backside dielectric layer.

12. The semiconductor structure of claim 11,
wherein the first bottom source/drain feature and the second bottom source/drain feature comprise silicon germanium and a p-type dopant,
wherein the first top source/drain feature and the second top source/drain feature comprise silicon and an n-type dopant.

13. The semiconductor structure of claim 11, wherein the first isolation feature is spaced apart from a sidewall of the first bottom source/drain feature by a plurality semiconductor features and a plurality of dielectric features.

14. The semiconductor structure of claim 11, wherein a top surface of the first isolation feature is spaced apart from a bottom surface of the first gate structure by a middle dielectric layer and a semiconductor layer.

15. The semiconductor structure of claim 11, further comprising:
a second plurality of channel members extending between the second bottom source/drain feature and a third bottom source/drain feature;
a second gate structure wrapping around each of the second plurality of channel members;
a third plurality of channel members extending between the second top source/drain feature and a third top source/drain feature;
a third gate structure wrapping around each of the third plurality of channel members;
a fourth plurality of channel members extending between the third bottom source/drain feature and a fourth bottom source/drain feature;
a fourth gate structure wrapping around each of the fourth plurality of channel members; and
a second isolation feature is disposed over the fourth gate structure.

16. The semiconductor structure of claim 15, further comprising:
a fourth top source/drain feature such that the second isolation feature is disposed between the third top source/drain feature and the fourth top source/drain feature;
a first frontside contact feature disposed over the third top source/drain feature;
a second frontside contact feature disposed over the fourth top source/drain feature; and
a second jumper feature interfacing the first frontside contact feature and the second frontside contact feature.

17. A device structure, comprising:
a first bottom transistor comprising a first plurality of nanostructures extending between a first bottom source/drain feature and a second bottom source/drain feature along a direction;
a first top transistor disposed over the first bottom transistor and comprising a second plurality of nanostructures extending between a first top source/drain feature and a second top source/drain feature along the direction;
a second top transistor sharing the first top source/drain feature with the first top transistor;
a second bottom transistor sharing the second bottom source/drain feature with the first bottom transistor;
a bottom isolation feature disposed below the second top transistor;
a top isolation feature disposed over the second bottom transistor;
a first jumper feature disposed below the bottom isolation feature;
a second jumper feature disposed over the top isolation feature;
a backside etch stop layer disposed below the first jumper feature; and
a backside dielectric layer below the backside etch stop layer,
wherein a composition of the backside etch stop layer is different from a composition of the backside dielectric layer.

18. The device structure of claim 17, where a bottom surface of the bottom isolation feature interfaces a top surface of the first jumper feature.

19. The device structure of claim 17, wherein a top surface of the top isolation feature is spaced apart from a bottom surface of the second jumper feature by an etch stop layer and an interlayer dielectric layer.

20. The device structure of claim 17, wherein the first bottom source/drain feature is spaced apart from a sidewall of the bottom isolation feature by a plurality of semiconductor features and a plurality of dielectric features.
